(19) United States
(12) Patent Application Publication
(10) Pub. No.: US 2025/0228056 A1
(43) Pub. Date: Jul. 10, 2025

(54) LIGHT EMITTING DEVICE

(71) Applicant: FUJIFILM Corporation, Tokyo (JP)

(72) Inventor: Hiroyuki OKUSA, Kanagawa (JP)

(73) Assignee: FUJIFILM Corporation, Tokyo (JP)

(21) Appl. No.: 19/091,402

(22) Filed: Mar. 26, 2025

Related U.S. Application Data
(63) Continuation of application No. PCT/JP2023/036396, filed on Oct. 5, 2023.

(30) Foreign Application Priority Data
Oct. 28, 2022 (JP) 2022-173190

(51) Int. Cl. H10H 29/855; G02B 5/22; G02B 5/30; H01L 25/075

(52) U.S. Cl. CPC H10H 29/8552; G02B 5/223; G02B 5/3016; H01L 25/0753

(57) ABSTRACT

A light emitting device having excellent utilization efficiency of light and suppressed external light reflection. The light emitting device includes a display element, a λ/4 plate, and a polarizer, in which the display element has a substrate, a plurality of light emitting elements disposed on the substrate, and a colored layer disposed on at least a part of a region on the substrate, where the light emitting elements are not present, the colored layer containing at least one colorant selected from the group consisting of a pigment and a dye, and an average visible light transmittance of the polarizer is 44% to 55%.

### CROSS-REFERENCE TO RELATED APPLICATIONS

This application is a Continuation of PCT International Application No. PCT/JP2023/036396 filed on Oct. 5, 2023, which was published under PCT Article 21(2) in Japanese, and which claims priority under 35 U.S.C. § 119(a) to Japanese Patent Application No. 2022-173190 filed on Oct. 28, 2022. The above applications are hereby expressly incorporated by reference, in their entirety, into the present application.

### BACKGROUND OF THE INVENTION

### 1. Field of the Invention

The present invention relates to a light emitting device.

### 2. Description of the Related Art

In recent years, as a display device that replaces a liquid crystal display device, a display device formed of a self-emission type light emitting element such as an organic electroluminescence (EL) display device or an inorganic electroluminescence (inorganic light emitting diode (LED)) display device has been developing.

An image display device reflects external light particularly in a bright environment and degrades the contrast.

Therefore, a self-light emitting type display device using a light emitting element such as an organic EL display device or an inorganic EL display device is provided with a circularly polarizing plate consisting of a polarizer and a λ/4 plate on the surface as an antireflection film (for example, see JP2009-259721A and JP2017-022016A).

### SUMMARY OF THE INVENTION

The present inventors have studied the introduction of a polarizer having a high average visible light transmittance into a self-emission type display device described in JP2009-259721A and JP2017-022016A from the viewpoint of improving the utilization efficiency of light, and have found that the effect of suppressing external light reflection is insufficient.

Therefore, an object of the present invention is to provide a light emitting device having excellent utilization efficiency of light and suppressed external light reflection.

As a result of intensive studies to achieve the above-described object, the present inventors have found that, in a case where a polarizer having a specific average visible light transmittance is used and a display element having a colored layer at a predetermined position is used, the utilization efficiency of light of a light emitting device is improved and external light reflection can be suppressed, thereby completing the present invention.

That is, the present inventor has found that the above-described objects can be achieved by employing the following configurations.

[1] A light emitting device comprising a display element, λ/4 plate, and a polarizer, in which the display element has a substrate, a plurality of light emitting elements disposed on the substrate, and a colored layer disposed on at least a part of a region on the substrate where the light emitting elements are not present, the colored layer containing at least one colorant selected from the group consisting of a pigment and a dye, and an average visible light transmittance of the polarizer is 44% to 55%.

[2] The light emitting device according to [1], in which the polarizer is a light absorption anisotropic film containing a liquid crystal compound and a dichroic substance.

[3] The light emitting device according to [1] or [2], in which a light emission loss rate of the colored layer is 1% to 20%.

[4] The light emitting device according to any one of [1] to [3], in which alight emission loss rate of the colored layer is 5% to 20%.

[5] The light emitting device according to any one of [1] to [4], in which an average value of thicknesses of the colored layers is smaller than an average value of heights of the light emitting elements.

[6] The light emitting device according to any one of [1] to [5], in which at least a part of the light emitting element is covered with a transparent layer containing neither a pigment nor a dye, or a low concentration colored layer containing at least one colorant selected from the group consisting of a pigment and a dye at a concentration lower than a concentration of the colorant in the colored layer.

[7] The light emitting device according to [2], in which, for a signal derived from the dichroic substance detected by time-of-flight secondary ion mass spectrometry, a relationship between a maximum intensity Imax of the light absorption anisotropic film in a thickness direction and an intensity Isur on a surface of the light absorption anisotropic film corresponding to a visible side of the light emitting device satisfies Expression (2),

$$2. \leq Imax / Isur . \qquad ( 2 )$$

[8] The light emitting device according to [2], in which an abundance of the dichroic substance per unit volume in the light absorption anisotropic film is 100 mg/cm³ or less.

[9] The light emitting device according to any one of [1] to [8], in which, in a case where the light emitting device is observed from a visible side, a relationship between an average visible light transmittance Ta of the polarizer in a region overlapping with the light emitting element and an average visible light transmittance Tb of the polarizer in a region other than the region satisfies Expression (3),

$$1. 5 \leq Ta / Tb \leq 2.5 . \qquad ( 3 )$$

[10] The light emitting device according to any one of [1] to [9], in which the light emitting element is an inorganic electroluminescent light emitting element.

According to the present invention, it is possible to provide a light emitting device in which the utilization efficiency of light is excellent and external light reflection is suppressed.

### BRIEF DESCRIPTION OF THE DRAWINGS

FIG. 1 is a schematic cross-sectional view showing an example of an embodiment of a light emitting device of the present invention.

FIG. 2 is a schematic cross-sectional view showing another example of an embodiment of a light emitting device of the present invention.

FIG. 3 is a schematic cross-sectional view showing another example of an embodiment of a light emitting device of the present invention.

FIG. 4 is a schematic cross-sectional view showing another example of an embodiment of a light emitting device of the present invention.

### DESCRIPTION OF THE PREFERRED EMBODIMENTS

Hereinafter, the present invention will be described in detail.

Although the configuration requirements to be described below may be described based on representative embodiments of the present invention, the present invention is not limited to such embodiments.

In the present specification, the numerical value range expressed by “to” means that the numerical values described before and after “to” are included as a lower limit value and an upper limit value, respectively.

In addition, in the present specification, for each component, one type of substance corresponding to each component may be used alone, or two or more types thereof may be used in combination. Here, in a case where two or more types of substances are used in combination for each component, the content of the component refers to a total content of the substances used in combination unless otherwise specified.

In the present specification, Re(λ) and Rth(λ) represent an in-plane retardation and a thickness-direction retardation at a wavelength λ, respectively. Unless otherwise specified, the wavelength λ refers to 550 nm.

In addition, in the present specification, Re(λ) and Rth(λ) are values measured at the wavelength λ using AxoScan (manufactured by Axometrics, Inc.).

Specifically, by inputting an average refractive index ((nx+ny+nz)/3) and a film thickness (d(μm)) to AxoScan,
in-plane slow axis direction (°),

$$Re ( λ ) = R 0 ( λ ) , \\ and \\ Rth ( λ ) = ( ( nx + ny ) / 2 - nz ) \times d$$

are calculated.

It is noted that, although R0(λ) is displayed as a numerical value calculated by AxoScan, it means Re(λ).

### [Light Emitting Device]

A light emitting device according to the embodiment of the present invention includes a display element, a λ/4 plate, and a polarizer.

In addition, the display element included in the light emitting device according to the embodiment of the present invention has a substrate, a plurality of light emitting elements disposed on the substrate, and a colored layer disposed on at least a part of a region on the substrate where the light emitting elements are not present, the colored layer containing at least one colorant selected from the group consisting of a pigment and a dye.

In addition, the average visible light transmittance of the polarizer included in the light emitting device according to the embodiment of the present invention is 44% to 55%.

In the present invention, as described above, by using a polarizer having an average visible light transmittance of 44% to 55% and using a display element in which a colored layer is disposed in at least a part of a region on a substrate where a light emitting element is not present, the utilization efficiency of light of the light emitting device is improved, and external light reflection can be suppressed.

A reason for achieving such an effect is not clear in detail, but is presumed to be as follows by the present inventors.

That is, it is considered that, by using a polarizer having an average visible light transmittance of 44% to 55%, the utilization efficiency of light can be improved while ensuring the polarization performance.

In addition, it is considered that, by using a display element in which a colored layer is disposed in at least a part of a region on a substrate where a light emitting element is not present, external light reflection can be suppressed.

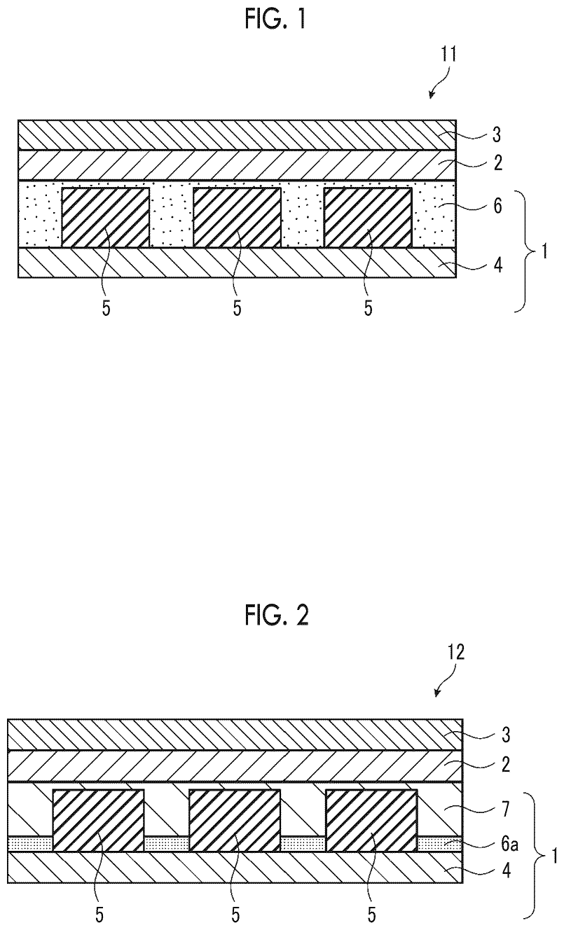

Hereinafter, after describing the embodiment of the light emitting device according to the embodiment of the present invention with reference to FIGS. 1 to 4, each configuration requirement of the light emitting device according to the embodiment of the present invention will be described.

A light emitting device 11 shown in FIG. 1 includes a display element 1, a λ/4 plate 2, and a polarizer 3.

In addition, the display element 1 includes a substrate 4, a plurality of light emitting elements 5 disposed on the substrate 4, and a colored layer 6 disposed in at least a part of a region on the substrate 4 where the light emitting element 5 is not present.

Here, as shown in FIG. 1, the colored layer 6 may be disposed in the entire region on the substrate 4 where the light emitting element 5 is not present, or may be disposed to cover the light emitting element 5.

A light emitting device 12 shown in FIG. 2 includes a display element 1, a λ/4 plate 2, and a polarizer 3.

In addition, the display element 1 includes a substrate 4, a plurality of light emitting elements 5 disposed on the substrate 4, a colored layer 6a disposed in the entire region on the substrate 4 where the light emitting element 5 is not present, and a transparent layer 7 disposed on the colored layer 6a and disposed to cover the light emitting element 5, the transparent layer 7 containing neither a pigment nor a dye. It is noted that the transparent layer 7 may be a low concentration colored layer containing at least one colorant selected from the group consisting of a pigment and a dye at a concentration lower than the concentration of the colorant in the colored layer 6a.

Here, as shown in FIG. 2, it is preferable that the colored layer 6a is disposed such that the average value of the thicknesses is lower than the average value of the heights of the light emitting elements 5.

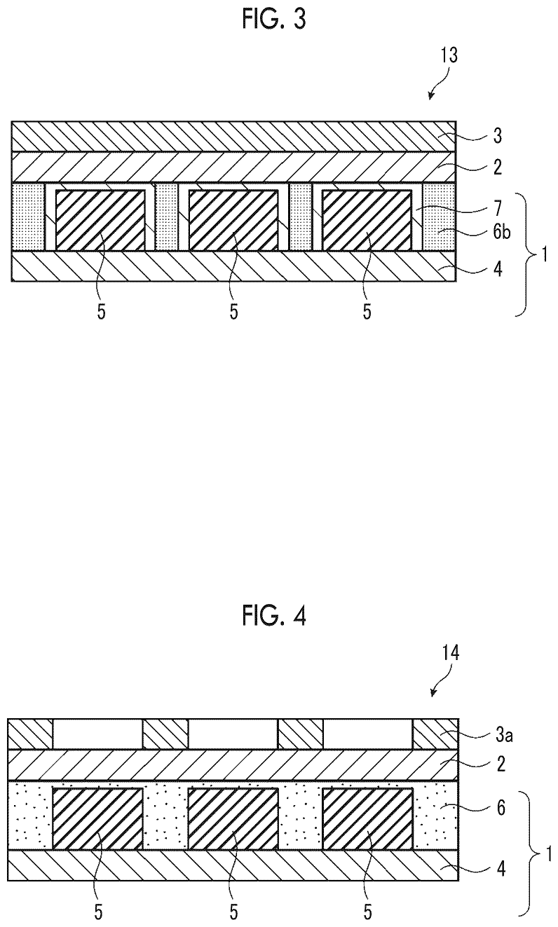

A light emitting device 12 shown in FIG. 3 includes a display element 1, a λ/4 plate 2, and a polarizer 3.

In addition, the display element 1 includes a substrate 4, a plurality of light emitting elements 5 disposed on the substrate 4, a colored layer 6b disposed in a part of a region on the substrate 4 where the light emitting element 5 is not present, and a transparent layer 7 disposed to cover the light emitting element 5, the transparent layer 7 containing neither a pigment nor a dye. It is noted that the transparent layer 7 may be a low concentration colored layer containing at least one colorant selected from the group consisting of a pigment and a dye at a concentration lower than the concentration of the colorant in the colored layer 6a.

A light emitting device 14 shown in FIG. 4 includes a display element 1, a λ/4 plate 2, and a polarizer 3a.

In addition, the display element 1 includes a substrate 4, a plurality of light emitting elements 5 disposed on the substrate 4, and a colored layer 6 disposed in at least a part of a region on the substrate 4 where the light emitting element 5 is not present.

Here, as shown in FIG. 4, it is preferable that the polarizer 3a is provided with an opening portion in a region overlapping with the light emitting element 5 in a case where the light emitting device 14 is observed from the visible side.

### [Display Element]

As described above, the display element included in the light emitting device according to the embodiment of the present invention has a substrate, a plurality of light emitting elements disposed on the substrate, and a colored layer disposed on at least a part of a region on the substrate where the light emitting elements are not present, the colored layer containing at least one colorant selected from the group consisting of a pigment and a dye.

### <Substrate>

As the substrate included in the display element, various element substrates used as an element substrate in an organic EL display device or an inorganic EL display device of a related art, or the like, such as a resin film and a glass substrate, can be utilized.

### <Light Emitting Element>

Examples of the plurality of light emitting elements included in the display element include an R light emitting element that emits red light, a G light emitting element that emits green light, and a B light emitting element that emits blue light.

In addition, it is preferable that the R light emitting elements, the G light emitting elements, and the B light emitting elements are two-dimensionally arranged in a large number, similarly to a known display element.

In addition, the area ratio of the light emitting element in the display element is not particularly limited, but is preferably 30% or less, more preferably 10% or less, and still more preferably 3% or less.

In the present invention, from the viewpoint of sufficiently obtaining brightness even in a case where the area ratio of the light emitting element in the display element is reduced, the light emitting element is preferably an inorganic EL light emitting element (so-called LED).

In addition, in the present invention, from the viewpoint of further improving the utilization efficiency of light, it is preferable that at least a part of the light emitting element is covered with a transparent layer containing neither a pigment nor a dye, or a low concentration colored layer containing at least one colorant selected from the group consisting of a pigment and a dye at a concentration lower than a concentration of the colorant in a colored layer described later, and it is more preferable that the entire light emitting element is covered with the transparent layer or the low concentration colored layer.

Here, the expression “at least a part of the light emitting element is covered with . . . ” is synonymous with that the transparent layer or the low concentration colored layer is disposed on at least a part of a surface or a side surface of the light emitting element.

In addition, it is more preferable that a concentration (C2) of the colorant in the transparent layer or the low concentration colored layer and a concentration (C1) of the colorant in the colored layer satisfy Expression (1).

$$0 \leq C 2 / C 1 \leq 0.3 \qquad ( 1 )$$

### <Colored Layer>

The colored layer included in the display element is a layer disposed in at least a part of a region on the substrate where the light emitting element is not present, the layer containing at least one colorant selected from the group consisting of a pigment and a dye.

Here, as described above, the colored layer may be disposed in the entire region on the substrate where the light emitting element is not present, or may be disposed to cover the light emitting element.

Examples of the pigment which is one type of the colorant include carbon black, chrome yellow, Hansa yellow, benzidine yellow, Threne yellow, quinoline yellow, pigment yellow, permanent orange GTR, pyrazolone orange, Vulcan orange, Watchung red, permanent red, brilliant carmine 3B, brilliant carmine 6B, DuPont oil red, pyrazolone red, Rhodamine B lake, lake red C, pigment red, rose bengal, aniline blue, ultramarine blue, Calco oil blue, methylene blue chloride, phthalocyanine blue, pigment blue, phthalocyanine green, and malachite green oxalate, and these may be used alone or in combination of two or more types thereof.

In addition, examples of the dye which is one type of the colorant include a pyrazole azo compound, a pyrromethene compound, an anilino azo compound, a triphenylmethane compound, an anthraquinone compound, a benzylidene compound, an oxonol compound, a pyrazolotriazole azo compound, a pyridone azo compound, a cyanine compound, a phenothiazine compound, and a pyrrolopyrazole azomethine compound, and these may be used alone or in combination of two or more types thereof.

The content of the colorant contained in the colored layer is preferably 0.5% to 50% by mass, more preferably 1% to 40% by mass, and still more preferably 2% to 30% by mass.

In the present invention, from the viewpoint of further improving the utilization efficiency of light, the light emission loss rate of the colored layer is preferably 1% to 20% and more preferably 5% to 20%.

Here, the light emission loss rate can be calculated as a ratio (reduction rate) of the amount of the brightness reduced of the display element having the colored layer to the brightness of the display element having a layer (transparent layer) in a state where the colorant is not contained in the colored layer.

In addition, a method of adjusting the light emission loss rate of the colored layer is not particularly limited, and examples thereof include a method of adjusting the content of the colorant contained in the colored layer.

In the present invention, from the viewpoint of further improving the utilization efficiency of light, it is preferable that the average value of the thicknesses of the colored layers (hereinafter, also referred to as “average thickness of colored layer”) is smaller than the average value of the heights of the light emitting elements (hereinafter, also referred to as “average height of light emitting element”). It is noted that the average thickness of the colored layer and the average height of the light emitting element are both in the same unit (m).

In addition, from the viewpoint of further improving the utilization efficiency of light, the average thickness of the colored layer is more preferably ½ or less and still more preferably ¼ or less of the average height of the light emitting element.

Here, the average thickness of the colored layer is an average value obtained by measuring the thicknesses of any five or more sites of the colored layer and arithmetically averaging the measured values, and the average height of the light emitting elements is an average value obtained by measuring the heights of a plurality of light emitting elements and arithmetically averaging the measured values.

### [λ/4 Plate]

The λ/4 plate included in the light emitting device according to the embodiment of the present invention is a plate having a λ/4 function, and specifically, a plate having a function of converting linearly polarized light having a specific wavelength into circularly polarized light (or circularly polarized light into linearly polarized light).

Specific examples of an aspect in which the λ/4 plate has a monolayer structure include a stretched polymer film and a retardation film in which an optically anisotropic layer having a λ/4 function is provided on a support. In addition, specific examples of an aspect in which the λ/4 plate has a multilayer structure include a broadband λ/4 plate obtained by laminating a λ/4 plate and a λ/2 plate.

Here, it is also preferable that the optically anisotropic layer having a λ/4 function has a layer obtained by immobilizing a uniformly aligned liquid crystal compound. For example, a layer in which rod-like liquid crystal compounds is uniformly aligned horizontally to the in-plane direction or a layer in which disk-like liquid crystal compounds is uniformly aligned vertically to the in-plane direction can be used. Furthermore, for example, an optically anisotropic layer having reverse dispersibility can be prepared by uniformly aligning rod-like liquid crystal compounds having reverse dispersibility and immobilizing the compounds with reference to JP2020-084070A and the like.

### [Polarizer]

The polarizer included in the light emitting device according to the embodiment of the present invention is not particularly limited as long as it is a member having a function of converting light into specific linearly polarized light and having an average visible light transmittance of 44% to 55%, and an absorption type polarizer and a reflection type polarizer known in the related art can be used.

Here, the average visible light transmittance denotes an arithmetic average value of the transmittances at every 5 nm in a visible light region (wavelength range of 400 nm to 700 nm). The transmittance is measured using a spectrophotometer (for example, a multi-channel spectroscope (product name, “QE65000”, manufactured by OCEAN OPTICS Inc.).

In addition, the average visible light transmittance of the polarizer is preferably 47% to 55% and more preferably 50% to 55%.

In the present invention, from the viewpoint of easily adjusting the average visible light transmittance of the polarizer to a range of 44% to 55%, the polarizer is preferably a light absorption anisotropic film containing a liquid crystal compound and a dichroic substance, and more preferably a light absorption anisotropic film in which the alignment state of the liquid crystal compound and the dichroic substance is fixed.

Hereinafter, the liquid crystal compound, the dichroic substance, and any components contained in the light absorption anisotropic film will be described.

### <Liquid Crystal Compound>

As such a liquid crystal compound, both a polymer liquid crystal compound and a low-molecular-weight liquid crystal compound can be used.

Here, the “polymer liquid crystal compound” refers to a liquid crystal compound having a repeating unit in the chemical structure.

In addition, the “low-molecular-weight liquid crystal compound” refers to a liquid crystal compound having no repeating unit in the chemical structure.

Examples of the polymer liquid crystal compound include thermotropic liquid crystal polymers described in JP2011-237513A and polymer liquid crystal compounds described in paragraphs [0012] to [0042] of WO2018/199096A.

Examples of the low-molecular-weight liquid crystal compound include liquid crystal compounds described in paragraphs [0072] to [0088] of JP2013-228706A. Among these, a smectic liquid crystal compound is preferable.

Examples of such a liquid crystal compound include those described in paragraphs [0019] to [0140] of WO2022/014340A, the description of which is incorporated herein by reference.

A content of the liquid crystal compound is preferably 50% to 99% by mass and more preferably 75% to 90% by mass with respect to the total mass of the light absorption anisotropic film.

### <Dichroic Substance>

In the present invention, the dichroic substance means a coloring agent having different absorbances depending on directions. The dichroic substance may or may not exhibit liquid crystallinity.

The dichroic substance is not particularly limited, and examples thereof include a visible light absorbing substance (dichroic coloring agent), a light emitting substance (fluorescent substance and phosphorescent substance), an ultraviolet absorbing substance, an infrared absorbing substance, a non-linear optical substance, a carbon nanotube, and an inorganic substance (for example, quantum rod). Further, dichroic substances (dichroic coloring agents) known in the related art can be used.

Specific examples thereof include those described in paragraphs [0067] to [0071] of JP2013-228706A, paragraphs [0008] to [0026] of JP2013-227532A, paragraphs [0008] to [0015] of JP2013-209367A, paragraphs [0045] to [0058] of JP2013-14883A, paragraphs [0012] to [0029] of JP2013-109090A, paragraphs [0009] to [0017] of JP2013-101328A, paragraphs [0051] to [0065] of JP2013-37353A, paragraphs [0049] to [0073] of JP2012-63387A, paragraphs [0016] to [0018] of JP1999-305036A (JP-H11-305036A), paragraphs [0009] to [0011] of JP2001-133630A, [0030] to [0169] of JP2011-215337A, paragraphs [0021] to [0075] of JP2010-106242A, paragraphs [0011] to [0025] of JP2010-215846A, paragraphs [0017] to [0069] of JP2011-048311A, paragraphs [0013] to [0133] of JP2011-213610A, paragraphs [0074] to [0246] of JP2011-237513A, paragraphs [0005] to [0051] of JP2016-006502A, paragraphs [0014] to [0032] of JP2018-053167A, paragraphs [0014] to [0033] of JP2020-11716A, paragraphs [0005] to [0041] of WO2016/060173A, paragraphs [0008] to [0062] of WO2016/136561A, paragraphs [0014] to [0033] of WO2017/154835A, paragraphs [0014] to [0033] of WO2017/154695A, paragraphs [0013] to [0037] of WO2017/195833A, paragraphs [0014] to [0034] of WO2018/164252A, paragraphs [0021] to [0030] of WO2018/186503A, paragraphs [0043] to [0063] of WO2019/189345A, paragraphs [0043] to [0085] of WO2019/225468A, paragraphs [0050] to [0074] of WO2020/004106A, and paragraphs [0015] to [0038] of WO2021/044843A.

In the present invention, as the dichroic substance, from the viewpoint of enhancing dichroism, a dichroic azo coloring agent compound is preferably used, and a dichroic azo coloring agent compound having a thienothiazole skeleton is more preferably used.

The dichroic azo coloring agent compound denotes an azo coloring agent compound having different absorbances depending on the direction. The dichroic azo coloring agent compound may or may not exhibit liquid crystallinity. In a case where the dichroic azo coloring agent compound exhibits liquid crystallinity, it may exhibit any of nematic properties or smectic properties may be exhibited. The temperature range in which the liquid crystal phase is exhibited is preferably room temperature (approximately 20° C. to 28° C.) to 300° C., and from the viewpoints of handleability and production suitability, more preferably 50° C. to 200° C.

In the present invention, from the viewpoint of tint adjustment, it is preferable to use at least at least one coloring agent compound (first dichroic azo coloring agent compound) having a maximal absorption wavelength in a wavelength range of 560 to 700 nm and at least one coloring agent compound (second dichroic azo coloring agent compound) having a maximal absorption wavelength in a wavelength range of 455 nm or more and less than 560 nm.

In the present invention, three or more dichroic azo coloring agent compounds may be used in combination. For example, from the viewpoint of making the light absorption anisotropic film close to black, it is preferable to use the first dichroic azo coloring agent compound, the second dichroic azo coloring agent compound, and at least one coloring agent compound (third dichroic azo coloring agent compound) having a maximal absorption wavelength in a wavelength range of 380 nm or more and less than 455 nm in combination.

In the present invention, the dichroic azo coloring agent compound preferably has a crosslinkable group.

Examples of the crosslinkable group include a (meth)acryloyl group, an epoxy group, an oxetanyl group, and a styryl group, and among these, a (meth)acryloyl group is preferable. It is noted that the “(meth)acryloyl group” is a notation representing an “acryloyl group” or a “methacryloyl group”.

In the present invention, from the viewpoint of further suppressing external light reflection, for a signal derived from the dichroic substance detected by time-of-flight secondary ion mass spectrometry, a relationship between a maximum intensity Imax of the light absorption anisotropic film in a thickness direction and an intensity Isur on a surface of the light absorption anisotropic film corresponding to a visible side of the light emitting device preferably satisfies Expression (2).

Here, examples of the aspect in which Expression (2) is satisfied include an aspect in which the dichroic substance present in the light absorption anisotropic film is unevenly distributed on the k/plate side in the light absorption anisotropic film.

$$2. \leq Imax / Isur \qquad ( 2 )$$

### (Measurement Method of TOF-SIMS)

In the present invention, the measurement using TOF-SIMS is performed in the following manner.

### (1) Device and Conditions

Device: TOF-SIMS 5 (manufactured by ION-TOF GmbH)
Depth direction analysis: combined with Ar ion sputtering
Measurement range: Raster scan of 128 points each in one direction and in a direction orthogonal thereto.
Polarity: posi, nega

### (2) Intensity Isur and Maximum Intensity Imax

The intensity of each of the following regions in the light absorption anisotropic film which is an object to be measured, is measured in a case where an area from the visible side surface of the light absorption anisotropic film to the surface on a side opposite to the visible side surface is measured in the thickness direction at a constant speed.

### (Intensity Isur)

The average value (average value of the intensities from the baseline) of the intensities of the fragments derived from the dichroic substance based on the mass spectrometry in a region of 1% from the visible side surface of the light absorption anisotropic film is defined as the intensity Isur in the visible side surface.

### (Maximum Intensity Imax)

The maximum value of the intensity (intensity from baseline) of the fragment derived from the dichroic substance based on the mass spectrometry in a region of 98% of the total thickness excluding a portion of 1% of the total thickness from each surface is defined as the maximum intensity Imax in the thickness direction.

### (3) In Regard to Object to be Measured

In a case where the light absorption anisotropic film which is an object to be measured is present in a form of a laminate having an adjacent layer, the visible side surface (that is, an interface with the adjacent layer) of the light absorption anisotropic film described above can be specified in terms that the intensity of a fragment derived from a liquid crystal compound detected from the light absorption anisotropic film based on the mass spectrometry and the intensity of a fragment derived from the largest amount of compound based on the mass spectrometry among fragments detected from the adjacent layer intersect with each other.

Further, the intensity of a fragment derived from the dichroic substance (hereinafter, also referred to as “measurement object dichroic substance” in this paragraph) having a maximal absorption wavelength in a wavelength range of 500 to 650 nm is measured based on the mass spectrometry in a case where the light absorption anisotropic film contains two or more kinds of dichroic substances, and the intensity of a fragment derived from the dichroic substance having the largest absorbance among the measurement object dichroic substances is measured based on the mass spectrometry in a case where the light absorption anisotropic film contains two or more kinds of measurement object dichroic substances.

In the present invention, from the viewpoint of further suppressing external light reflection, the abundance of the dichroic substance present in the light absorption anisotropic film per unit volume is preferably 100 mg/cm³ or less, more preferably 40 to 95 mg/cm³, and still more preferably 50 to 90 mg/cm³. In a case where a plurality of dichroic substances are used in combination, the total amount of the plurality of dichroic substances is preferably within the above range.

Here, the abundance (mg/cm³) of the dichroic substance is obtained by measuring a solution, obtained by dissolving an optical laminate having the light absorption anisotropic film, or an extraction liquid, obtained by immersing an optical laminate in a solvent, using high performance liquid chromatography (HPLC, but the measurement method is not limited to the above-described method. In addition, the quantification can be performed by using the dichroic substance contained in the light absorption anisotropic film as a standard sample.

Examples of the method of calculating the abundance (mg/cm³) of the dichroic substance include a method in which the volume is calculated by multiplying the thickness of the light absorption anisotropic film obtained from a microscopic observation image of a cross section of the optical laminate by the area of the optical laminate used for measuring the coloring agent amount, and is divided by the coloring agent amount measured by HPLC to calculate the content of the coloring agent.

In the present invention, from the viewpoint of further improving the utilization efficiency of light, in a case where the light emitting device is observed from a visible side, a relationship between an average visible light transmittance Ta of the polarizer in a region overlapping with the light emitting element and an average visible light transmittance Tb of the polarizer in a region other than the region preferably satisfies Expression (3).

Specific examples of the aspect satisfying Expression (3) include an aspect in which in the polarizer, an opening portion is provided in a region overlapping with the light emitting element in a case where the light emitting device is observed from the visible side, as shown in FIG. 4.

$$1. 5 \leq Ta / Tb \leq 2.5 \qquad ( 3 )$$

### EXAMPLES

Hereinafter, the present invention will be described in more detail with reference to Examples. The materials, amounts used, proportions, treatment details, treatment procedures, and the like shown in the following examples can be appropriately changed as long as not departing from the gist of the present invention. Accordingly, the scope of the present invention should not be construed as being limited to Examples shown below.

### Example 1

### [Production of Transparent Support]

The following composition was put into a mixing tank and stirred, thereby preparing a cellulose acetate solution used as a core layer cellulose acylate dope.

Core layer cellulose acylate dope

| | |
|---|---|
| Cellulose acetate having acetyl substitution | 100 parts by mass |
| degree of 2.88 | |
| Polyester compound B described in Examples | 12 parts by mass |
| of JP2015-227955A | |
| Compound F described below | 2 parts by mass |
| Methylene chloride (first solvent) | 430 parts by mass |
| Methanol (second solvent) | 64 parts by mass |

Compound F

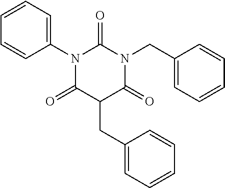 [SMILES: O=C1C(Cc2ccccc2)C(=O)N(c2ccccc2)C(=O)N1Cc1ccccc1]

10 parts by mass of the following matting agent solution was added to 90 parts by mass of the above-described core layer cellulose acylate dope, thereby preparing a cellulose acetate solution used as an outer layer cellulose acylate dope.

Matting agent solution

| | | |
|---|---|---|
| Silica particles having a average particle size | 2 | parts by mass |
| of 20 nm | | |
| (AEROSIL R972, manufactured by Nippon | | |
| Aerosil Co., Ltd.) | | |
| Methylene chloride (first solvent) | 76 | parts by mass |
| Methanol (second solvent) | 11 | parts by mass |
| Core layer cellulose acylate dope described above | 1 | part by mass |

The core layer cellulose acylate dope and the outer layer cellulose acylate dope were filtered through filter paper having an average pore size of 34 m and a sintered metal filter having an average pore size of 10 m, and three layers which were the core layer cellulose acylate dope and the outer layer cellulose acylate dopes provided on both sides of the core layer cellulose acylate dope were simultaneously cast from a casting port onto a drum at 20° C. (band casting machine).

Next, the film on the drum was peeled off in a state in which the solvent content in the film was approximately 20% by mass, both ends of the film in the width direction were fixed by tenter clips, and the film was dried while being stretched at a stretching ratio of 1.1 times in the lateral direction.

Then, the obtained film was transported between rolls of a heat treatment apparatus to be further dried to prepare a transparent support having a thickness of 40 m, which was used as a cellulose acylate film A1.

### [Formation of Photo-Alignment Film B1]

The above-described cellulose acylate film A1 was continuously coated with a composition B1 for forming a photo-alignment film described below with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film B1, thereby obtaining a triacetyl cellulose (TAC) film with the photo-alignment film. A film thickness of the photo-alignment film B1 was 0.25 km.

Composition B1 for forming photo-alignment film

| | |
|---|---|
| Polymer PA-1 shown below | 100.00 parts by mass |
| Acid generator PAG-1 shown below | 8.25 parts by mass |
| Stabilizer DIPEA shown below | 0.6 parts by mass |
| Xylene | 1126.60 parts by mass |
| Methyl isobutyl ketone | 125.18 parts by mass |

Polymer PA-1 [in the formulae, the numerical value described in each repeating
unit denotes the content (% by mass) of each repetition with respect to all
repeating units.] 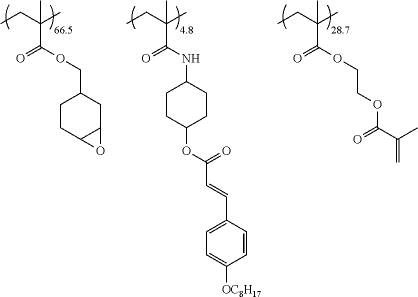
Acid generator PAG-1 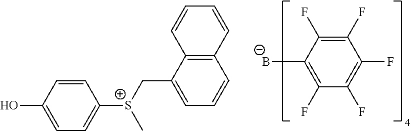
Stabilizer DIPEA

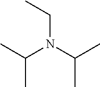

### [Production of Polarizer (Light Absorption Anisotropic Film C1)]

### <Coating Film Forming Step>

A coating film was formed by continuously coating the obtained photo-alignment film B1 with a composition C1 for forming a light absorption anisotropic film, having the following composition, with a wire bar.

### <Alignment Step>

Next, the coating film was heated at 140° C. for 15 seconds, and then cooled to room temperature (23° C.).

Next, the coating film was heated at 75° C. for 60 seconds, and was cooled to room temperature again.

Next, the coating layer was irradiated with light using a LED lamp (central wavelength: 365 nm) for 2 seconds under an irradiation condition of an illuminance of 200 mW/cm² to prepare the light absorption anisotropic film C1 (polarizer) (thickness: 0.4 μm) on the photo-alignment film B1.

In a case where a transmittance of the light absorption anisotropic film C1 in a wavelength range of 280 to 780 nm was measured with a spectrophotometer, the average visible light transmittance was 50%. The absorption axis of the light absorption anisotropic film C1 was orthogonal to a width direction of the cellulose acylate film A1.

In addition, the abundance of the dichroic substance in the light absorption anisotropic film C1 per unit volume was confirmed by the above-described method to be 170 mg/cm³.

Composition C1 for forming light absorption anistropic film

| | |
|---|---|
| First dichroic substance Dye-C1 shown below | 0.45 parts by mass |
| Second dichroic substance Dye-M1 shown below | 0.20 parts by mass |
| Third dichroic substance Dye-Y1 shown below | 0.18 parts by mass |
| Liquid crystal compound (L-1) shown below | 2.39 parts by mass |
| Liquid crystal compound (L-2) shown below | 1.34 parts by mass |
| Adhesion improver (A-1) | 0.15 parts by mass |
| Polymerization initiator IRGACURE OXE-02 (manufactured by BASF SE) | 0.15 parts by mass |
| Surfactant (F-1) shown below | 0.03 parts by mass |
| Cyclopentanone | 92.75 parts by mass |
| Benzyl alcohol | 2.38 parts by mass |

Dichroic substance Dye-C1 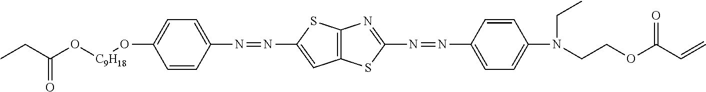
Dichroic substance Dye-M1 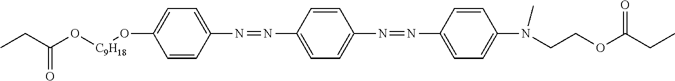
Dichroic substance Dye-Y1 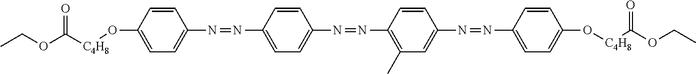
Liquid crystal compound (L-1) [in the formulae, the numerical value (“59”, “15”, or “26”) described in each repeating unit denotes
the content (% by mass) of each repetition with respect to all repeating units.] 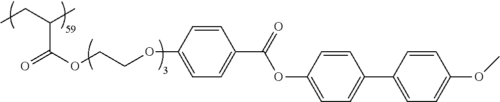 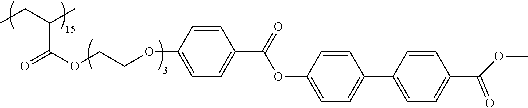 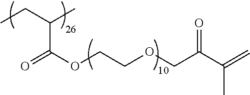
Liquid crystal compound (L-2) [mixture of liquid crystal compounds (RA), (RB), and (RC) shown below at a ratio of 84:14:2 (mass ratio)]
(RA) 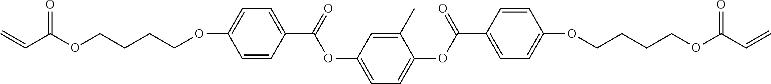 [SMILES: C=CC(=O)OCCCCOc1ccc(C(=O)Oc2ccc(OC(=O)c3ccc(OCCCCOC(=O)C=C)cc3)c(C)c2)cc1]
(RB) 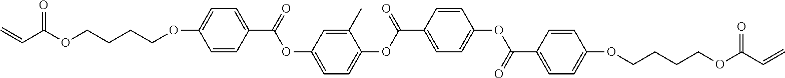 [SMILES: C=CC(=O)OCCCCOc1ccc(C(=O)Oc2ccc(C(=O)Oc3ccc(OC(=O)c4ccc(OCCCCOC(=O)C=C)cc4)cc3C)cc2)cc1]
(RC) 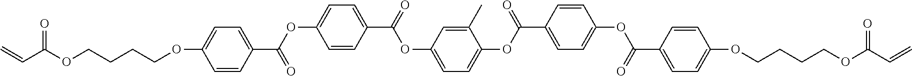 [SMILES: C=CC(=O)OCCCCOc1ccc(C(=O)Oc2ccc(C(=O)Oc3ccc(OC(=O)c4ccc(OC(=O)c5ccc(OCCCCOC(=O)C=C)cc5)cc4)c(C)c3)cc2)cc1]
Adhesion improver (A-1) 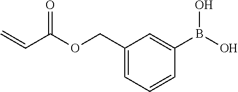
Surfactant (F-1) [in the formulae, the numerical value described in each repeating unit denotes the content (% by mass) of each repetition with respect to
all repeating units.]

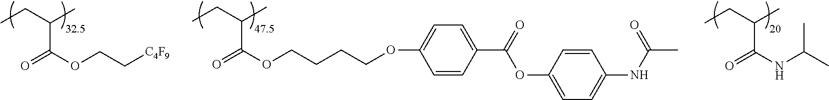

### [Formation of Oxygen-Shielding Layer D1]

The light absorption anisotropic film C1 was continuously coated with a coating solution D1 for forming an oxygen-shielding layer with the following composition using a wire bar. Thereafter, the film was dried with hot air at 80° C. for 5 minutes, thereby obtaining a laminate on which an oxygen-shielding layer D1 consisting of polyvinyl alcohol (PVA) and having a thickness of 1.0 m was formed, that is, obtaining a laminate CP1 in which the cellulose acylate film A1 (transparent support), the photo-alignment film B1, the light absorption anisotropic film C1, and the oxygen-shielding layer D1 were provided adjacent to each other in this order.

Formulation of coating liquid for forming oxygen-shielding layer D1

| | |
|---|---|
| Modified polyvinyl alcohol shown below | 3.80 parts by mass |
| Initiator IRGACURE 2959 | 0.20 parts by mass |
| Water | 70 parts by mass |
| Methanol | 30 parts by mass |

Modified polyvinyl alcohol [in the formulae, the numerical value described in each
repeating unit represents a content (% of mass) of each repeating unit with respect
to all repeating units.]

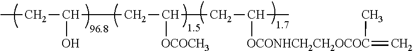

### [Production of TAC Film Including Positive a Plate]

The above-described cellulose acylate film A1 was continuously coated with a composition E1 for forming a photo-alignment film, having the following composition, with a wire bar. The support on which the coating film had been formed was dried with hot air at 140° C. for 120 seconds, and the coating film was irradiated with polarized ultraviolet rays (10 mJ/cm², using an ultra-high pressure mercury lamp) to form a photo-alignment film E1 having a thickness of 0.2 m, thereby obtaining a TAC film with the photo-alignment film.

Composition E1 for forming photo-alignment film

| | |
|---|---|
| Polymer PA-2 shown below | 100.00 parts by mass |
| Acid generator PAG-1 shown above | 5.00 parts by mass |
| Acid generator CPI-110TF shown below | 0.005 parts by mass |
| Isopropyl alcohol | 16.50 parts by mass |
| Butyl acetate | 1072.00 parts by mass |
| Methyl ethyl ketone | 268.00 parts by mass |

Polymer PA-2 [in the formulae, the numerical value described in each repeating
unit denotes the content (% by mass) of each repetition with aspect to all repeating
units.] 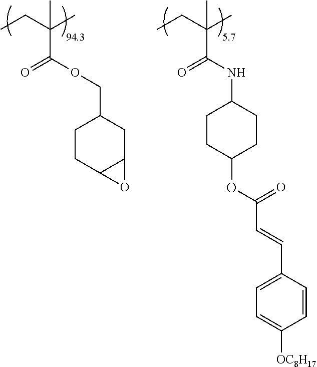
Acid generator CPI-110TF

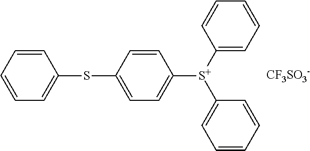

The above-described photo-alignment film E1 was coated with a composition F1 having the following composition using a bar coater. The coating film formed on the photo-alignment film E1 was heated to 120° C. with hot air, and then cooled to 60° C. The coating film was irradiated with ultraviolet rays having a wavelength of 365 nm with an illuminance of 100 mJ/cm² using a high-pressure mercury lamp in a nitrogen atmosphere, and continuously irradiated with ultraviolet rays with an illuminance of 500 mJ/cm² while being heated at 120° C., thereby the alignment of the liquid crystal compound was immobilized. Therefore, thereby producing a TAC film having a positive A plate F1.

The thickness of the positive A plate F1 was 2.5 μm, Re(550) was 144 nm, and the positive A plate F1 was a plate having a λ/4 function. In addition, the positive A plate satisfied a relationship of “Re(450)≤Re(550)≤Re(650)”. Re(450)/Re(550) was 0.82.

Composition F1

| | |
|---|---|
| Polymerizable liquid crystal compound LA-1 shown below | 43.50 parts by mass |
| Polymerizable liquid crystal compound LA-2 shown below | 43.50 parts by mass |
| Polymerizable liquid crystal compound LA-3 shown below | 8.00 parts by mass |
| Polymerizable liquid crystal compound LA-4 shown below | 5.00 parts by mass |
| Polmerizable initiator PI-1 shown below | 0.55 parts by mass |
| Leveling agent T-1 described below | 0.20 parts by mass |
| Cyclopentanone | 235.00 parts by mass |

Polymerizable liquid crystal compound LA-1 (tBu represents a tert-butyl group) 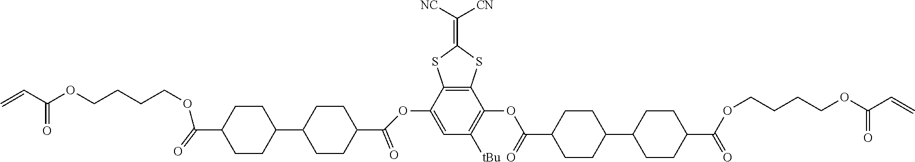 [SMILES: C=CC(=O)OCCCCOC(=O)C1CCC(C2CCC(C(=O)Oc3cc(C(C)(C)C)c(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-2 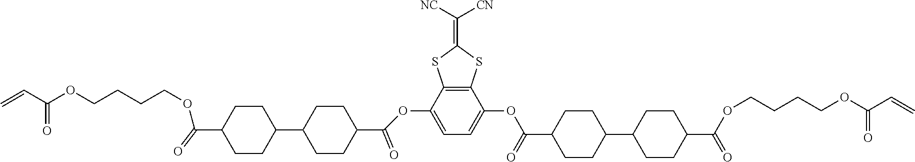 [SMILES: C=CC(=O)OCCCCOC(=O)C1CCC(C2CCC(C(=O)Oc3ccc(OC(=O)C4CCC(C5CCC(C(=O)OCCCCOC(=O)C=C)CC5)CC4)c4c3SC(=C(C#N)C#N)S4)CC2)CC1]
Polymerizable liquid crystal compound LA-3 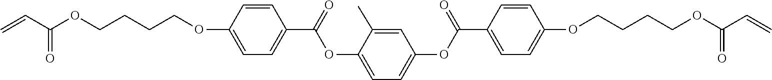 [SMILES: C=CC(=O)OCCCCOc1ccc(C(=O)Oc2ccc(OC(=O)c3ccc(OCCCCOC(=O)C=C)cc3)c(C)c2)cc1]
Polymerizable liquid crystal compound LA-4 (Me represents a methyl group) 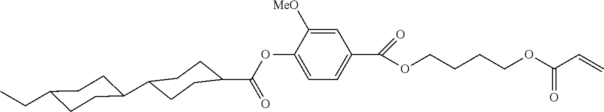 [SMILES: C=CC(=O)OCCCCOC(=O)c1ccc(OC(=O)C2CCC(C3CCC(CC)CC3)CC2)c(OC)c1]
Polymerization initiator PI-1 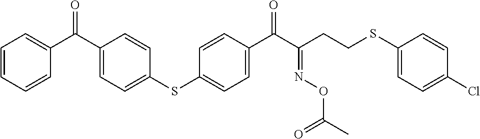 [SMILES: CC(=O)O/N=C(\CCSc1ccc(Cl)cc1)C(=O)c1ccc(Sc2ccc(C(=O)c3ccccc3)cc2)cc1]
Leveling agent T-1 [in the formulae, the numerical value described in each repeating unit denotes the content (% by mass) of each repetition with respect to
all repeating units.]

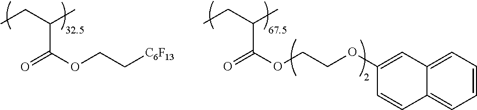

### [Production of TAC Film Including Positive C Plate H1]

The above-described cellulose acylate film A1 was used as a temporary support.

After passing the cellulose acylate film A1 through a dielectric heating roll at a temperature of 60° C. to raise the film surface temperature to 40° C., an alkaline solution having the composition shown below was applied onto one surface of the film using a bar coater at a coating amount of 14 ml/m², followed by heating to 110° C., and transportation of the film under a steam type far-infrared heater manufactured by Noritake Company Limited for 10 seconds.

Next, the film was coated with pure water such that the coating amount reached 3 ml/m² using the same bar coater. Next, the film was washed with water by a fountain coater and drained by an air knife three times, and then transported to a drying zone at 70° C. for 10 seconds and dried to produce a cellulose acylate film A1 subjected to an alkali saponification treatment.

(Alkaline solution)

| | | |
|---|---|---|
| Potassium hydroxide | 4.7 | parts by mass |
| Water | 15.8 | parts by mass |
| Isopropanol | 63.7 | parts by mass |
| Fluorine-containing surfactant SF-1 | 1.0 | parts by mass |
| (C₁₄H₂₉O(CH₂CH₂O)₂₀H) | | |
| Propylene glycol | 14.8 | parts by mass |

The cellulose acylate film A1 which had been subjected to the alkali saponification treatment was continuously coated with a composition G1 for forming a photo-alignment film, having the following composition, using a #8 wire bar. The obtained film was dried with hot air at 60° C. for 60 seconds, and further dried with hot air at 100° C. for 120 seconds to form a photo-alignment film G1.

Composition G1 for forming photo-alignment film

| | | |
|---|---|---|
| Polyvinyl alcohol (manufactured by Kuraray | 2.4 | parts by |
| Co., Ltd., PVA103) | | |
| Isopropyl alcohol | 1.6 | parts by |
| Methanol | 36 | parts by |
| Water | 60 | parts by |

The photo-alignment film G1 was coated with a coating liquid H1 for forming a positive C plate, having the following composition, the obtained coating film was aged at 60° C. for 60 seconds and irradiated with ultraviolet rays at an illuminance of 1000 mJ/cm² in the air using an air-cooled metal halide lamp at an illuminance of 70 mW/cm² (manufactured by Eye Graphics Co., Ltd.), and the alignment state thereof was fixed to vertically align the liquid crystal compound, thereby producing a TAC film having a positive C plate H1 with a thickness of 0.5 μm.

The Rth (550) of the obtained positive C plate was −60 nm.

Coating liquid H1 for forming positive C plate

| | |
|---|---|
| Liquid crystal compound LC-1 shown below | 80 parts by mass |
| Liquid crystal compound LC-2 shown below | 20 parts by mass |
| Vertically aligned liquid crystal compound S01 | 1 part by mass |
| Ethylene oxide-modified trimethylolpropane triacrylate (V#360, manufactured by Osaka Organic Chemical Industry Ltd.) | 8 parts by mass |
| IRGACURE 907 (manufactured by BASF SE) | 3 parts by mass |
| KAYACURE DETX (manufactured by Nippon Kayaku Co., Ltd.) | 1 parts by mass |
| Compound B03 shown below | 0.4 parts by mass |
| Methyl ethyl ketone | 170 parts by mass |
| Cyclohexanone | 30 parts by mass |

Liquid crystal compound LC-1 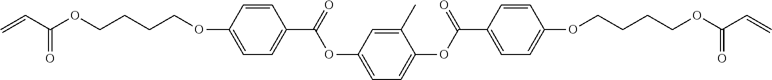 [SMILES: C=CC(=O)OCCCCOc1ccc(C(=O)Oc2ccc(OC(=O)c3ccc(OCCCCOC(=O)C=C)cc3)c(C)c2)cc1]
Liquid crystal compound LC-2 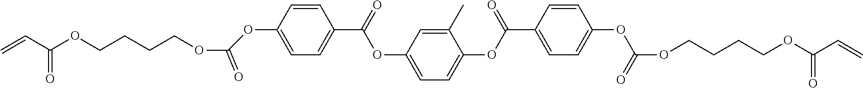 [SMILES: C=CC(=O)OCCCCOC(=O)Oc1ccc(C(=O)Oc2ccc(OC(=O)c3ccc(OC(=O)OCCCCOC(=O)C=C)cc3)c(C)c2)cc1]
Vertically aligned liquid crystal compound S01 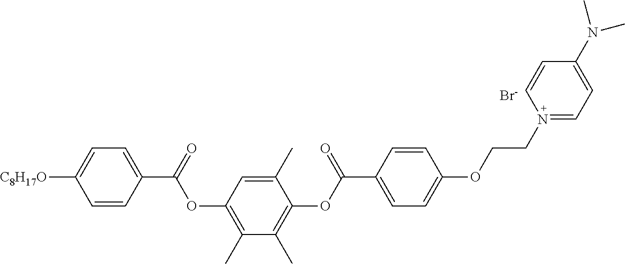
Compound B03 [in the formulae, the numerical value described in each repeating unit denotes the content (% by mass) of each repetition with respect to
all repeating units.]

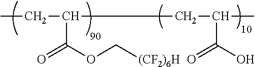

### [Production of Pressure Sensitive Adhesives N1 and N2]

Next, an acrylate-based polymer was prepared according to the following procedures.

95 parts by mass of butyl acrylate and 5 parts by mass of acrylic acid were polymerized by a solution polymerization method in a reaction container equipped with a cooling pipe, a nitrogen introduction pipe, a thermometer, and a stirrer, thereby obtaining an acrylate-based polymer (NA1) with an average molecular weight of 2,000,000 and a molecular weight distribution (Mw/Mn) of 3.0.

Next, an acrylate-based pressure sensitive adhesive was produced with the following formulation using the obtained acrylate-based polymer (NA1). Each separate film which had been subjected to a surface treatment with a silicone-based release agent was coated with the composition using a die coater, dried in an environment of 90° C. for 1 minute, and irradiated with ultraviolet rays (UV) under the following conditions, thereby obtaining the following acrylate-based pressure sensitive adhesives N1 and N2 (pressure-sensitive adhesive layers). The composition and the film thickness of the acrylate-based pressure sensitive adhesive are shown below.

### <UV Irradiation Conditions>

Electrodeless lamp H bulb (Fusion Co., Ltd.)
Illuminance of 600 mW/cm², light intensity of 150 mJ/cm²
The UV illuminance and the light intensity were measured using “UVPF-36” manufactured by Eye Graphics Co., Ltd.

Acrylate-based pressure sensitive adhesive
N1 (film thickness of 15 μm)

| | | |
|---|---|---|
| Acrylate-based polymer (NA1) | 100 | parts by mass |
| (A) Polyfunctional acrylate-based monomer | 11.1 | parts by mass |
| shown below | | |
| (B) Photopolymerization initiator shown below | 1.1 | parts by mass |
| (C) Isocyanate-based crosslinking agent | 1.0 | part by mass |
| shown below | | |
| (D) Silane coupling agent shown below | 0.2 | parts by mass |

Acrylate-based pressure sensitive adhesive
N2 (film thickness of 25 μm)

| | | |
|---|---|---|
| Acrylate-based polymer (NA1) | 100 | parts by mass |
| (C) Isocyanate-based crosslinking | 1.0 | part by mass |
| agent shown below | | |
| (D) Silane coupling agent shown below | 0.2 | parts by mass |

(A) Polyfunctional acrylate-based monomer: tris(acryloyloxyethyl) isocyanurate, molecular weight=423, trifunctional type (manufactured by Toagosei Co., Ltd., trade name “ARONIX M-315”)
(B) Photopolymerization initiator: mixture of benzophenone and 1-hydroxycyclohexyl phenyl ketone at mass ratio of 1:1, “IRGACURE 500” manufactured by Ciba Specialty Chemicals Corp.
(C) Isocyanate-based crosslinking agent: trimethylolpropane-modified tolylene diisocyanate (“CORONATE L” manufactured by Nippon Polyurethane Industry Co., Ltd.)
(D) Silane coupling agent: 3-glycidoxypropyltrimethoxysilane (“KBM-403”, manufactured by Shin-Etsu Chemical Co., Ltd.)

### [Production of UV Adhesive]

A UV adhesive composition having the following composition was prepared.

UV adhesive composition

| | |
|---|---|
| CEL2021P (manufactured by Daicel Corporation) | 70 parts by mass |
| shown below | |
| 1,4-Butanediol diglycidyl ether | 20 parts by mass |
| 2-Ethylhexyl glycidyl ether | 10 parts by mass |
| CIP-100P | 2.25 parts by mass |

CPI-100P

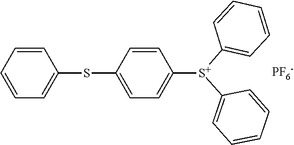

### [Production of Laminate CPAC1]

The above-described TAC film having the positive A plate F1 on the phase difference side and the above-described TAC film having the positive C plate H1 on the phase difference side were bonded to each other by irradiation with UV rays of 600 mJ/cm² using the above-described UV adhesive composition. A thickness of the UV adhesive layer was 3 m. The surfaces bonded to each other with the UV adhesive were respectively subjected to a corona treatment. Next, the photo-alignment film E1 on the positive A plate F1 side and the cellulose acylate film A1 were removed to obtain a retardation plate AC1. The retardation plate AC1 had a layer configuration of the positive A plate F1, the UV adhesive layer, the positive C plate H1, the photo-alignment film G1, and the cellulose acylate film A1.

The above-described laminate CP1 on the oxygen-shielding layer D1 side was bonded to a low-reflection surface film CV-LC5 (manufactured by FUJIFILM Corporation) on a support side using the above-described pressure sensitive adhesive N1. Next, only the cellulose acylate film A1 of the above-described laminate CP1 was removed, and the surface from which the film had been removed and the retardation plate AC1 on the positive A plate F1 side were bonded to each other using the above-described pressure sensitive adhesive N1. Next, the photo-alignment film G1 on the positive C plate H1 side and the cellulose acylate film A1 included in the above-described retardation plate AC1 were removed, thereby producing a laminate CPAC1. At this time, the films were bonded to each other such that an angle between an absorption axis of the light absorption anisotropic film C1 included in the above-described laminate CPAC1 and a slow axis of the positive A plate F1 was set to 45°. The laminate CPAC1 had a layer configuration of the low-reflection surface film CV-LC5, the pressure sensitive adhesive layer N1, the oxygen-shielding layer D1, the light absorption anisotropic film C1, the photo-alignment film B1, the pressure sensitive adhesive N1, the positive A plate F1, the UV adhesive layer, and the positive C plate H1.

### [Production of LED Display Device (Display Device 1)]

Three-color light emitting LEDs (PICOLED, model number: SMLP34RGB, manufactured by Rohm Co., Ltd.) were arranged on a printed circuit board in a two-dimensional lattice form such that the area ratio of the LEDs (light emitting elements) was 30%, and buried with a colored layer 1 composed of a black matrix material.

Next, in a case where the brightness was measured from a distance of 700 mm using a spectroscopic luminance meter (manufactured by TOPCON TECHNOHOUSE CORPORATION, SR3), the light emission loss rate of a sample produced by the same method except that a transparent layer composed of a transparent resin material was used instead of the colored layer 1, was 1%.

Next, the positive C plate H1 side of the laminate CPAC1 produced above was bonded to the colored layer 1 such that air did not enter, thereby producing an LED display device (display device 1).

### Example 2

An LED display device (display device 2) was produced according to the same procedure as in Example 1, except that a light absorption anisotropic film in which the thickness was adjusted such that the average visible light transmittance was 44% using the composition C1 for forming a light absorption anisotropic film was used instead of the light absorption anisotropic film C1.

### Example 3

An LED display device (display device 3) was produced according to the same procedure as in Example 1, except that a colored layer having a light emission loss rate of 20% was used instead of the colored layer 1.

### Example 4

A LED display device (display device 4) was produced according to the same procedure as in Example 1, except that a colored layer having a light emission loss rate of 20% was used instead of the colored layer 1, and a light absorption anisotropic film in which the thickness was adjusted such that the average visible light transmittance was 44% using the composition C1 for forming a light absorption anisotropic film was used instead of the light absorption anisotropic film C1.

### Example 5

A LED display device (display device 5) was produced according to the same procedure as in Example 1, except that a colored layer having a light emission loss rate of 10% was used instead of the colored layer 1, and a light absorption anisotropic film in which the thickness was adjusted such that the average visible light transmittance was 47% using the composition C1 for forming a light absorption anisotropic film was used instead of the light absorption anisotropic film C1.

### Example 6

A LED display device (display device 6) was produced according to the same procedure as in Example 1, except that a colored layer having a light emission loss rate of 10% was formed instead of the colored layer 1 up to ⅕ of the height of the light emitting element from the print substrate, and a transparent layer not having a black matrix material was formed on the upper layer of the colored layer to embed the light emitting element.

### Example 7

A LED display device (display device 7) was produced according to the same procedure as in Example 1, except that a colored layer having a light emission loss rate of 10% was formed not to be provided around the light emitting element instead of the colored layer 1, and a transparent layer having no black matrix material was formed around the light emitting element to embed the light emitting element.

### Example 8

An LED display device (display device 8) was produced according to the same procedure as in Example 1, except that a light absorption anisotropic film formed of a composition C2 for forming a light absorption anisotropic film having the following composition was used, and a colored layer having a light emission loss rate of 10% was used instead of the colored layer 1. It is noted that the abundance of the dichroic substance in the formed light absorption anisotropic film per unit volume was confirmed by the above-described method to be 170 mg/cm³.

Composition C2 for forming light absorption anisotropic film

| | |
|---|---|
| First dichroic substance Dye-C1 shown above | 0.65 parts by mass |
| Second dichroic substance Dye-M1 shown above | 0.15 parts by mass |
| Third dichroic substance Dye-Y1 shown above | 0.52 parts by mass |
| Liquid crystal compound (L-1) shown above | 2.68 parts by mass |
| Liquid crystal compound (L-2) shown above | 1.15 parts by mass |
| Adhesion improver (A-1) | 0.17 parts by mass |
| Polymerization initiator | 0.17 parts by mass |
| IRGACURE OXE-02 (manufactured by | |
| BASF SE) | |
| Surfactant (F-1) shown above | 0.02 parts by mass |
| Cyclopentanone | 92.14 parts by mass |
| Benzyl alcohol | 2.36 parts by mass |

In Example 8, in a case where a signal derived from the dichroic substance detected by the time-of-flight secondary ion mass spectrometry was confirmed by the method described above, it was confirmed that a relationship between the maximum intensity Imax of the light absorption anisotropic film in the thickness direction and the intensity Isur on the surface of the light absorption anisotropic film corresponding to the visible side of the light emitting device satisfied Expression (2).

$$2. \leq Imax / Isur \qquad ( 2 )$$

### Example 9

A laminate was produced according to the same procedure as in Example 1, except that the transparent support, the photo-alignment film, and the light absorption anisotropic film shown below were used in the production of the laminate CPAC1, and the step of removing the transparent support was not included.

Next, a LED display device (display device 9) was produced according to the same procedure as in Example 1, except that the produced laminate was used and a colored layer having a light emission loss rate of 10% was used instead of the colored layer 1.

With the following composition, a composition E2 for forming a photo-alignment film was prepared, dissolved for 1 hour while stirring, and filtered with a filter of 0.45 μm.

Composition E2 for forming photo-alignment film

| | |
|---|---|
| Photoactive compound E-4 shown below | 5.0 parts by mass |
| Cyclopentanone | 95.0 parts by mass |

Photoactive compound E-4 (weight-average molecular weight: 51,000)

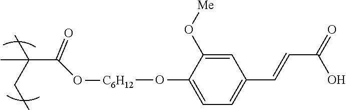

A composition P1 for forming a light absorption anisotropic film was prepared with the following composition, dissolved by heating at 80° C. for 2 hours with stirring, and filtered through a 0.45 μm filter.

Composition P1 for forming light absorption anisotropic film

| | |
|---|---|
| Dichroic coloring agent D1 shown below | 0.8 parts by mass |
| Dichroic coloring agent D2 shown below | 2.6 parts by mass |
| Dichroic coloring agent D3 shown below | 2.2 parts by mass |
| Dichroic coloring agent D4 shown below | 1.8 parts by mass |
| Liquid crystal compound M1 shown below | 100.0 parts by mass |
| Polymerization initiator IRGACURE 369 (manufactured by BASF SE) | 5.0 parts by mass |
| BYK361N (manufactured by BYK Chemie Japan Co., Ltd.) | 0.9 parts by mass |
| Cyclopentanone | 925.0 parts by mass |

Dichroic coloring agent D1 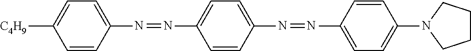
Dichroic coloring agent D2 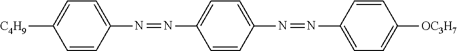
Dichroic coloring agent D3 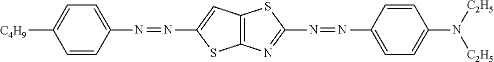
Dichroic coloring agent D4 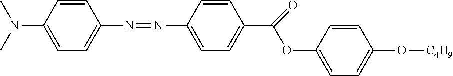
Liquid crystal compound M1 (mixing at Compound A and Compound B = 75/25)
(Compound A) 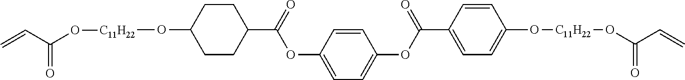
(Compound B)

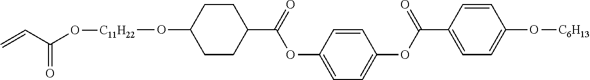

The composition E2 for forming a photo-alignment film was applied onto a cellulose triacetate film TJ40 (manufactured by FUJIFILM Corporation, thickness of 40 m) as a transparent support and dried at 60° C. for 2 minutes. Thereafter, the obtained coating film was irradiated with linearly polarized ultraviolet rays (100 mJ/cm²) using a polarized ultraviolet exposure device to produce a photo-alignment film E2.

The obtained photo-alignment film E2 was coated with the composition P1 for forming a light absorption anisotropic film using a wire bar. Next, the obtained coating film was heated at 120° C. for 60 seconds and cooled to room temperature.

Thereafter, the coating film was irradiated with ultraviolet rays at an exposure amount of 2,000 mJ/cm² using a high-pressure mercury lamp to form a light absorption anisotropic film P1 having a thickness of 1.7 m.

It was confirmed that the liquid crystal of the light absorption anisotropic film was a smectic B phase and had the average visible light transmittance of 50%.

In addition, in a case where the abundance of the dichroic substance in the formed light absorption anisotropic film P1 per unit volume was confirmed by the above-described method to be 65 mg/cm³.

### Example 10

A laminate was produced according to the same procedure as in Example 1, except that the transparent support, the photo-alignment film, and the light absorption anisotropic film shown below were used in the production of the laminate CPAC1, and the step of removing the photo-alignment film was included.

Next, a LED display device (display device 10) was produced according to the same procedure as in Example 1, except that the produced laminate was used and a colored layer having a light emission loss rate of 10% was used instead of the colored layer 1.

### <Production of Transparent Support>

A TAC base material (TG40, manufactured by FUJIFILM Corporation) having a thickness of 40 m was continuously coated with a polymer coating solution having the following composition using a #8 wire bar. Thereafter, the base material was dried with hot air at 100° C. for 2 minutes, thereby obtaining a support in which a polyvinyl alcohol (PVA) polymer film having a thickness of 0.8 m was formed on the TAC base material.

Furthermore, modified polyvinyl alcohol was added to the polymer coating solution such that the concentration of solid contents was set to 4% by mass.

Composition of polymer coating solution

| | |
|---|---|
| Modified polyvinyl alcohol shown below | |
| Water | 70 parts by mass |
| Methanol | 30 parts by mass |

Modified polyvinyl alcohol [in the formulae, the numerical value described in each
repeating unit represents a content (% by mass) of each repeating unit with respect to
all repeating units.]

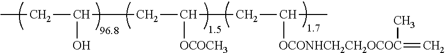

### <Formation of Alignment Film>

41.6 parts by mass of butoxyethanol, 41.6 parts by mass of dipropylene glycol monomethyl, and 15.8 parts by mass of pure water were added to 1 part by mass of a photo-alignment material E-1 having the following structure, and the obtained solution was filtered through a 0.45 m membrane filter under pressure, thereby preparing a coating solution for a photo-alignment film.

Next, the produced transparent support was coated with the obtained coating solution for a photo-alignment film and dried at 60° C. for 1 minute. Thereafter, the obtained coating film was irradiated with linearly polarized ultraviolet rays (illuminance of 4.5 mW/cm², integrated irradiation amount of 300 mJ/cm²) using a polarized ultraviolet exposure device (first light irradiation), thereby preparing a photo-alignment film having an alignment restricting force in the horizontal direction. The thickness of the photo-alignment film was 50 nm.

Next, the obtained photo-alignment film was irradiated with non-polarized ultraviolet rays (illuminance of 4.5 mW/cm², integrated irradiation amount of 2,000 mJ/cm²) in a direction perpendicular to the film surface via a photomask (second light irradiation), thereby preparing a pattern-exposed photo-alignment film.

As the mask pattern of the mask, a mask pattern having a light shielding portion and a light transmitting portion, with the light shielding portion corresponding to a position of the light emitting element (area ratio of 30%) of the above-described LED display device (display device 1) was used.

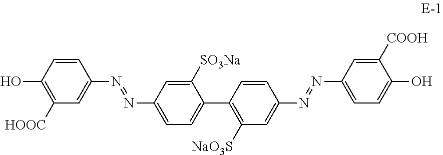

### <Production of Light Absorption Anisotropic Film>

The obtained pattern-exposed photo-alignment film was continuously coated with a composition F1 for forming a light absorption anisotropic film having the following composition using a wire bar to form a coating layer F.

Next, the coating layer F was heated at 140° C. for 15 seconds, and the coating layer F was cooled to room temperature (23° C.).

Next, the coating layer was heated at 75° C. for 60 seconds and cooled to room temperature again.

Thereafter, the coating layer was irradiated with an LED lamp (center wavelength of 365 nm) for 2 seconds under an irradiation condition of an illuminance of 200 mW/cm², thereby producing a light absorption anisotropic film having the region A and the region B with different inclinations of the absorption axes with respect to the film surface on the pattern-exposed alignment film and having an average visible light transmittance of 55%.

Composition of composition F1 for forming light absorption anisotropic film

| | |
|---|---|
| First dichroic substance C-1 shown below | 0.65 parts by mass |
| Second dichroic substance M-1 shown below | 0.15 parts by mass |
| Third dichroic substance Y-1 shown below | 0.52 parts by mass |
| Liquid crystal compound L-1 shown below | 2.68 parts by mass |
| Liquid crystal compound L-2 shown below | 1.15 parts by mass |
| Polymerization initiator IRGACURE OXE-02 (manufactured by BASF SE) | 0.17 parts by mass |
| Surfactant S-1 shown below | 0.020 parts by mass |
| Cyclopentanone | 92.14 parts by mass |
| Benzyl alcohol | 2.36 parts by mass |

Dichroic substance C-1 (maximal absorption wavelength: 570 nm) 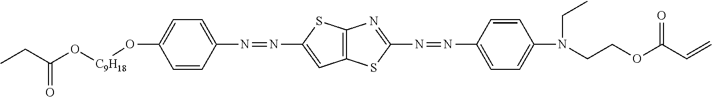
Dichroic substance M-1 (maximal absorption wavelength: 466 nm) 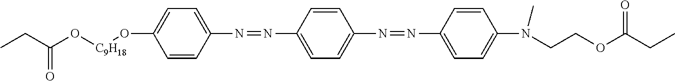
Dichroic substance Y-1 (Maximal Absorption Wavelength: 417 nm) 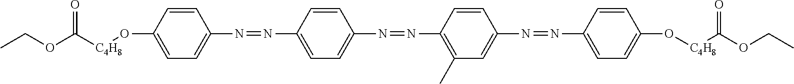
Liquid crystal compound L-1 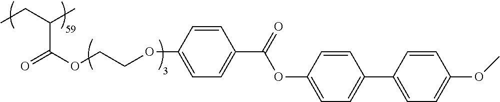 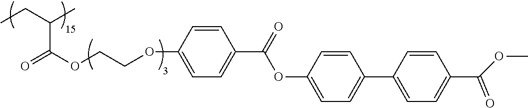 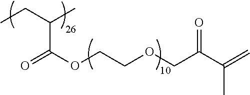
Liquid crystal compound L-2 [mixture of the following liquid crystal compounds (RA), (RB), and (RC) at a ratio of 84:14:2 (mass ratio)]
(RA) 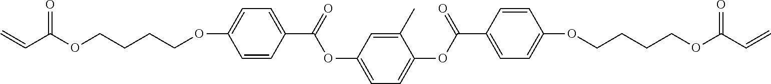 [SMILES: C=CC(=O)OCCCCOc1ccc(C(=O)Oc2ccc(OC(=O)c3ccc(OCCCCOC(=O)C=C)cc3)c(C)c2)cc1]
(RB) 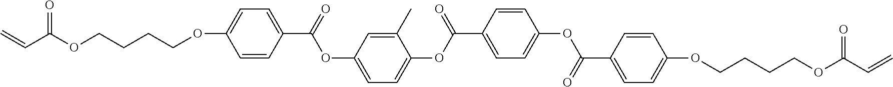 [SMILES: C=CC(=O)OCCCCOc1ccc(C(=O)Oc2ccc(C(=O)Oc3ccc(OC(=O)c4ccc(OCCCCOC(=O)C=C)cc4)cc3C)cc2)cc1]
(RC) 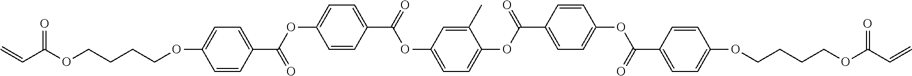 [SMILES: C=CC(=O)OCCCCOc1ccc(C(=O)Oc2ccc(C(=O)Oc3ccc(OC(=O)c4ccc(OC(=O)c5ccc(OCCCCOC(=O)C=C)cc5)cc4)c(C)c3)cc2)cc1]
Surfactant S-1 [in the formulae, the numerical value described in each repeating unit denotes the content (% by mass) of each repetition with respect to
all repeating units.]

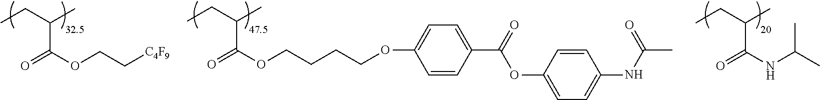

In Example 10, in a case where the produced LED display device (display device 10) was observed from the visible side, a relationship between the average visible light transmittance Ta of the polarizer in the region overlapping with the light emitting element and the average visible light transmitance Tb of the polarizer in the region other than the above-described region was examined, and it was found that Expression (3) was satisfied.

$$1. 5 \leq Ta / Tb \leq 2.5 \qquad ( 3 )$$

### Comparative Example 1

A LED display device (display device C1) was produced according to the same procedure as in Example 1, except that a transparent layer composed of a transparent resin material was used instead of the colored layer 1 and a light absorption anisotropic film having a average visible light transmittance of 47% was used instead of the light absorption anisotropic film C1.

### Comparative Example 2

A LED display device (display device C2) was produced according to the same procedure as in Example 1 except that a colored layer having a light emission loss rate of 40% was used instead of the colored layer 1 and the step of bonding the laminate CPAC1 onto the colored layer 1 was not included. That is, a light emitting device not including the λ/4 plate and the polarizer was produced.

### Comparative Example 3

A LED display device (display device C3) was produced according to the same procedure as in Example 1, except that a colored layer having a light emission loss rate of 10% was used instead of the colored layer 1, and a light absorption anisotropic film having a average visible light transmittance of 56% was used instead of the light absorption anisotropic film C1.

### Comparative Example 4

A LED display device (display device C4) was produced according to the same procedure as in Example 1, except that a colored layer having a light emission loss rate of 20% was used instead of the colored layer 1, and a light absorption anisotropic film having a average visible light transmittance of 42% was used instead of the light absorption anisotropic film C1.

### Evaluation

### [Utilization Efficiency of Light]

The brightness was measured at a distance of 700 mm from the display surface of the prepared display device using a spectral brightness meter (SR3, manufactured by Topcon Technohouse Corporation) to evaluate the utilization efficiency of light of the light emitting element.

Specifically, a transparent layer composed of a transparent resin material was used instead of the colored layer, and the ratio (light utilization efficiency) of the brightness of the produced display device to the brightness of the LED display device not having the laminate CPAC1 was evaluated according to the following standards. The results are shown in Table 1.
A: 48% or more
B: 42% or more and less than 48%
C: 35% or more and less than 42%
D: less than 35%

### [Suppression of External Light Reflection]

For the produced display device, the value of Y in the SCI measuring method was measured 10 times using a spectrocolorimeter (CM2022, manufactured by Konica Minolta, Inc.) at different positions in the plane, and the average value thereof was calculated as the reflectivity.

Using the calculated reflectivity, the effect of suppressing external light reflection was evaluated according to the following standard. The results are shown in Table 1.
A: less than 2%.
B: 2% or more and less than 4%
C: 4% or more and less than 5%
D: case of 5% or more

TABLE 1

| | | | | Evaluation | |
|---|---|---|---|---|---|
| | | | Polarizer | | Suppression |
| | | Colored layer | Average | Utilization | of external |
| | | Light emission | visible light | efficiency of | light |
| | Configuration | loss rate | transmittance | light | reflection |
| Example 1 | FIG. 1 | 1% | 50% | A | C |
| Example 2 | FIG. 1 | 1% | 44% | B | B |
| Example 3 | FIG. 1 | 20% | 50% | C | B |
| Example 4 | FIG. 1 | 20% | 44% | C | A |
| Example 5 | FIG. 1 | 10% | 47% | B | A |
| Example 6 | FIG. 2 | 10% | 50% | B | A |
| Example 7 | FIG. 3 | 10% | 50% | B | A |
| Example 8 | FIG. 1 | 10% | 50% | B | A |
| Example 9 | FIG. 1 | 10% | 50% | B | A |
| Example 10 | FIG. 4 | 10% | 55% | A | A |
| Comparative | FIG. 1 | — | 47% | B | D |
| Example 1 | | | | | |
| Comparative | — | 40% | — | A | D |
| Example 2 | | | | | |
| Comparative | FIG. 1 | 10% | 56% | A | D |
| Example 3 | | | | | |
| Comparative | FIG. 1 | 20% | 42% | D | A |
| Example 4 | | | | | |

From the results shown in Table 1, it was found that even in a case where the average visible light transmittance of the polarizer was 4400 to 5500 the effect of suppressing external light reflection was insufficient in a case where the display element did not have the colored layer (Comparative Example 1).

In addition, it was found that the effect of suppressing external light reflection was insufficient in a case where the λ/4 plate and the polarizer were not included (Comparative Example 2).

In addition, it was found that in a case where the average visible light transmittance of the polarizer was 56%, the effect of suppressing external light reflection was insufficient (Comparative Example 3).

In addition, it was found that in a case where the average visible light transmittance of the polarizer was 42%, the utilization efficiency of light was decreased (Comparative Example 4).

On the other hand, it was found that in a case where a polarizer having an average visible light transmittance of 44% to 55% was used and a display element including a colored layer was used, the utilization efficiency of light of the light emitting device was improved, and the external light reflection could be suppressed (Examples 1 to 10).

### EXPLANATION OF REFERENCES

1: display element
2: λ/4 plate
3, 3a: polarizer
4: substrate
5: light emitting element
6, 6a, 6b: colored layer
7: transparent layer
11, 12, 13: display device

What is claimed is:

1. A light emitting device comprising:
a display element;
a λ/4 plate; and
a polarizer,
wherein the display element has a substrate, a plurality of light emitting elements disposed on the substrate, and a colored layer disposed on at least a part of a region on the substrate, where the light emitting elements are not present, the colored layer containing at least one colorant selected from the group consisting of a pigment and a dye, and
an average visible light transmittance of the polarizer is 44% to 55%.

2. The light emitting device according to claim 1,
wherein the polarizer is a light absorption anisotropic film containing a liquid crystal compound and a dichroic substance.

3. The light emitting device according to claim 1,
wherein a light emission loss rate of the colored layer is 1% to 20%.

4. The light emitting device according to claim 1,
wherein a light emission loss rate of the colored layer is 5% to 20%.

5. The light emitting device according to claim 1,
wherein an average value of thicknesses of the colored layers is smaller than an average value of heights of the light emitting elements.

6. The light emitting device according to claim 1,
wherein at least a part of the light emitting element is covered with a transparent layer containing neither a pigment nor a dye, or a low concentration colored layer containing at least one colorant selected from the group consisting of a pigment and a dye at a concentration lower than a concentration of the colorant in the colored layer.

7. The light emitting device according to claim 2,
wherein, for a signal derived from the dichroic substance detected by time-of-flight secondary ion mass spectrometry, a relationship between a maximum intensity Imax of the light absorption anisotropic film in a thickness direction and an intensity Isur on a surface of the light absorption anisotropic film corresponding to a visible side of the light emitting device satisfies Expression (2),
$$2. \leq Imax / Isur . \qquad ( 2 )$$

8. The light emitting device according to claim 2,
wherein an abundance of the dichroic substance per unit volume in the light absorption anisotropic film is 100 mg/cm³ or less.

9. The light emitting device according to claim 1,
wherein, in a case where the light emitting device is observed from a visible side, a relationship between an average visible light transmittance Ta of the polarizer in a region overlapping with the light emitting element and an average visible light transmittance Tb of the polarizer in a region other than the region satisfies Expression (3),
$$1. 5 \leq Ta / Tb \leq 2.5 . \qquad ( 3 )$$

10. The light emitting device according to claim 1,
wherein the light emitting element is an inorganic electroluminescent light emitting element.

11. The light emitting device according to claim 2,
wherein a light emission loss rate of the colored layer is 1% to 20%.

12. The light emitting device according to claim 2,
wherein a light emission loss rate of the colored layer is 5% to 20%.

13. The light emitting device according to claim 2,
wherein an average value of thicknesses of the colored layers is smaller than an average value of heights of the light emitting elements.

14. The light emitting device according to claim 2,
wherein at least a part of the light emitting element is covered with a transparent layer containing neither a pigment nor a dye, or a low concentration colored layer containing at least one colorant selected from the group consisting of a pigment and a dye at a concentration lower than a concentration of the colorant in the colored layer.

15. The light emitting device according to claim 2,
wherein, in a case where the light emitting device is observed from a visible side, a relationship between an average visible light transmittance Ta of the polarizer in a region overlapping with the light emitting element and an average visible light transmittance Tb of the polarizer in a region other than the region satisfies Expression (3),
$$1. 5 \leq Ta / Tb \leq 2.5 . \qquad ( 3 )$$

16. The light emitting device according to claim 2,
wherein the light emitting element is an inorganic electroluminescent light emitting element.

17. The light emitting device according to claim 3,
wherein a light emission loss rate of the colored layer is 5% to 20%.

18. The light emitting device according to claim 3,
wherein an average value of thicknesses of the colored layers is smaller than an average value of heights of the light emitting elements.

19. The light emitting device according to claim 3,
wherein at least a part of the light emitting element is covered with a transparent layer containing neither a pigment nor a dye, or a low concentration colored layer containing at least one colorant selected from the group consisting of a pigment and a dye at a concentration lower than a concentration of the colorant in the colored layer.

20. The light emitting device according to claim 3,
wherein, in a case where the light emitting device is observed from a visible side, a relationship between an average visible light transmittance Ta of the polarizer in a region overlapping with the light emitting element and an average visible light transmittance Tb of the polarizer in a region other than the region satisfies Expression (3),
$$1. 5 \leq Ta / Tb \leq 2.5 . \qquad ( 3 )$$
